(19) United States
(12) Patent Application Publication
(10) Pub. No.: US 2026/0189253 A1
(43) Pub. Date: Jul. 2, 2026

(54) AMPLIFIER CORRECTION AND BEAMFORMING ARRANGEMENT

(71) Applicant: Argo Semiconductors SA, Hellinikon (GR)

(72) Inventors: Georgios VOLANIS, Chania (GR); Konstantinos VRYSAS, Athens (GR); Georgios SFIKAS, Athens (GR); Emmanouil FRANTZESKAKIS, Athens (GR)

(73) Assignee: Argo Semiconductors SA, Hellinikon (GR)

(21) Appl. No.: 19/003,843

(22) Filed: Dec. 27, 2024

(51) Int. Cl. H04B 1/04; G06N 3/08; H03F 1/32; H03F 3/24; H04B 7/06

(52) U.S. Cl. CPC H04B 1/0475; G06N 3/08; H03F 1/3282; H03F 3/245; H04B 7/0617; H04B 2001/0425

(57) ABSTRACT

Apparatus for causing a power amplifier (PA) to act as an idealized power amplifier (iPA). The apparatus comprises: a fixed digital predistortion (DPD) circuit; a PA coupled to the DPD circuit, the PA receiving as an input a version of a signal supplied as an output by the DPD and the PA supplying as an output an amplified version of the PA input; and a neural network adapted to control a level of amplification provided by the PA; wherein the neural network receives an indication of the input to the PA and an indication of output of the PA and controls the level of amplification provided by the PA based on the received indications.

### TECHNICAL FIELD

This invention relates to wireless communication, and in particular, to wireless communication that employs multiple antennas and beamforming.

### BACKGROUND

Massive multiple input multiple output (mMIMO) technology is considered, as of this writing, as typically employing 16 antennas or more for wireless communication, whereas most commonly used are arrays of 32 antennas. Other, higher numbers of antennas, e.g., 64, may also be employed. mMIMO, by using a large number of antennas, is able to support two or more users at one time instant using the same frequency, which may be achieved by pointing an individual beam at each user using beamforming. mMIMO is expected to be a major contributor to the success of fifth generation wireless technology (5G) as it promises to provide better exploitation of the space dimension in service of increasing wireless network capability. Herein, the term 5G is meant to refer to the current generation of mobile networks as specified by the International Telecommunications Union-Radio communications sector (ITU-R) and/or the 3rd Generation Partnership Project (3GPP), which is well known to those of ordinary skill in the art.

mMIMO systems require an analog front end (AFE) unit to provide to the antennas amplified signals for transmission and to amplify signals received by the antennas. In the transmit direction, each AFE unit amplifies the signal it receives that is to be transmitted. These signals have already been upconverted from baseband to the frequency of interest for transmission. Each AFE unit then supplies the amplified signal it produced to one antenna element (AE) of an antenna array, which is an array of M antenna elements, each of which is also referred to herein simply as an antenna, e.g., via a respective antenna feeding port. As such, there may be a bank of AFE units that is made up of M individual AFE units.

To this end, each AFE unit contains a power amplifier (PA) to amplify the signal for transmission that is supplied to the antennas coupled to the AFE unit. The PA is typically an amplifier producing a high-power output that has at least a range of operation of which a portion thereof is not linear in amplification and may also introduce a phase distortion. Since it is desirable to use as much of the range of the PA as possible, digital pre-distortion (DPD) is employed to modify the input to the PA to provide for an effective linear operation of the PA, i.e., to reduce the distortion created by running the PA in any nonlinear regions. DPD is a cost-effective linearization technique which aims to provide improved linearity, better efficiency, and to take full advantage of the PA. DPD typically functions by modifying an original signal for transmission to produce the signal supplied to the PA using modification values from a lookup table (LUT) which are used to modify the original signal for transmission. The LUT is developed based on feedback of the output of the PA as compared to what is supplied thereto as input.

More specifically, DPD may use the LUT to properly distort the original signal for transmission, the resulting distorted signal being the signal actually supplied to the PA. Such distorted signal, i.e., the output of the DPD, is generated so that when it is supplied to the PA the signal output by the PA is expected to be a linearly amplified version of the original signal for transmission, i.e., prior to undergoing DPD.

In addition, in the receive direction, each AFE unit amplifies signals received by the at least one antenna coupled to it. Individual AFE units may be coupled to more than one antenna which may be connected together to one feeding port. Because the received signal may be weak, e.g., received from a distant transmitter with limited power, a low-noise amplifier (LNA) is typically used so that minimal noise is added to the weak received signal, which may already be close to the level of noise.

Often, 5G systems operate in a time division duplex (TDD) fashion, so that they transmit during a first time period and then receive during a second, subsequent time period, where the first and second time periods alternate. As such, the AFE unit includes a switch to switch from transmit mode to receive mode and vice versa. While such a switch may have various operating modes, the primary function is to couple the amplified signal for transmission from the PA to the one or more antennas coupled to the front end unit, e.g., via a feeding port, during the first time period and to couple the antennas to a LNA during the second time period.

Disadvantageously, in a communication system, DPD is typically done individually for each PA based on feedback therefor, which can be complicated and computationally intensive.

### SUMMARY

A summary of several example embodiments of the disclosure follows. This summary is provided for the convenience of the reader to provide a basic understanding of such embodiments and does not wholly define the breadth of the disclosure. This summary is not an extensive overview of all contemplated embodiments and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “certain embodiments” may be used herein to refer to a single embodiment or multiple embodiments of the disclosure.

Certain embodiments disclosed herein include apparatus for causing a power amplifier (PA) to act as an idealized power amplifier (iPA). The apparatus comprises: a fixed digital predistortion (DPD) circuit; a PA coupled to the DPD circuit, the PA receiving as an input a version of a signal supplied as an output by the DPD and the PA supplying as an output an amplified version of the PA input; and a neural network adapted to control a level of amplification provided by the PA; wherein the neural network receives an indication of the input to the PA and an indication of output of the PA and controls the level of amplification provided by the PA based on the received indications.

Certain embodiments disclosed herein include a beamforming transmitter for use in wireless communication. The beamforming transmitter comprises: a plurality of fixed digital predistortion (DPD) circuits each receiving a respective input for transmission and supplying as an output an adjusted version of its received input; a plurality of filtering and gain chains, each of the plurality of filtering and gain chains receiving as input a respective one of the adjusted versions of the inputs; and a plurality of idealized beamformers (iBFs), each iBF of the plurality being coupled to receive as input an output supplied from one of the filtering and chain gains and supplying as output an amplified version of its respective received input for transmission by at least one antenna, wherein each of the filtering and gain chains supplies its output to a plurality of the iBFs, wherein each iBF comprises: a power amplifier (PA); a neural network adapted to control a level of amplification provided by the PA based an indication of the input to the PA and an indication of output of the PA which are supplied to the neural network; and an analog beamformer interposed between input to the iBF and the PA of the iBF, the analog beamformer controlling at least one of phase and amplitude of an output signal based on the input to the iBF.

### BRIEF DESCRIPTION OF THE DRAWING

In the drawing:

FIG. 1 shows an embodiment of the disclosure that employs a fixed DPD and an idealized power amplifier (iPA), i.e., a power amplifier in that it has been arranged to behave as if it conforms to a known non-linear amplification curve through the use of a NN that responds to sensors coupled to the PA;

FIG. 2 shows a more detailed illustrative view of an embodiment of both the iPA and edge computing/storage resources of FIG. 1;

FIG. 3 shows that multiple iPAs may each transmit their own data to a NN training mechanism (NNTM) and receive from updated weights from the NNTM;

FIG. 4 shows an illustrative arrangement of an embodiment of the disclosure that employs a fixed DPD and an idealized power amplifier (iPA) similar to that shown in FIG. 1 but which is attached to a single antenna for use with an analog beamforming implementation;

FIG. 5 shows an illustrative arrangement of an embodiment of the disclosure that employs a single fixed DPD and an idealized power amplifier (iPA) while implementing analog beamforming similar to that shown in FIG. 4 but which further employs a pre-power amplifier that is further controlled by an additional neural network;

FIG. 6 shows an illustrative arrangement of an embodiment of the disclosure that employs a single fixed DPD and at least two idealized beamformers to implement analog beamforming;

FIG. 7 shows an illustrative arrangement of a hybrid analog-digital beamforming radio in accordance with an embodiment of the disclosure;

FIG. 8 shows an illustrative arrangement of a hybrid analog-digital beamforming radio in accordance with another embodiment of the disclosure;

FIG. 9 shows an illustrative system according to an embodiment; and.

FIG. 10 shows an embodiment similar to that of FIG. 1 but where the iPA, further includes sensors 1015 that may sense various conditions such as temperature, voltage, technology process, and the like, in or adjacent to the PA of the iPA.

### DETAILED DESCRIPTION

It is important to note that the embodiments disclosed herein are only examples of the many advantageous uses of the innovative teachings herein. In general, statements made in the specification of the present application do not necessarily limit any of the various claimed embodiments. Moreover, some statements may apply to some inventive features but not to others. In general, unless otherwise indicated, singular elements may be in plural and vice versa with no loss of generality. In the drawings, like numerals refer to like parts through several views.

In their prior application, U.S. patent application Ser. No. 18/400,728, filed on Dec. 29, 2023, assigned to the same assignee and incorporated by references as if fully set forth herein, an improvement was made in the art by employing, a fixed, i.e., not adaptive, linearizing element, e.g., fixed or feed-forward digital pre-distortion (DPD), to adjust the signals eventually applied to a power amplifier (PA). To achieve this, linearization is done in part in the analog domain using for each PA an analog neural network (NN), also referred to as a supervisor, to make all PA behave as if they have the same non-linear amplification curve using data from at least one sensor adapted to determine at least one condition, such as temperature, voltage, technology process, and the like, related to of the power amplifier. In particular, the NN may “idealize” each PA, i.e., cause it to behave like an ideal PA with a known amplification curve regardless of actual conditions experienced by the PA such as temperature, voltage, technology process, and the like which tend to change the operation of the PA. Advantageously, as a result, a fixed DPD, which is relatively simple as compared to the adaptive, and hence computationally intensive, DPDs previously employed in the art may be used because the fixed DPD effectively sees a static PA. The training of the analog NN may take place in the cloud and the linearization techniques may be employed with both analog and digital beamforming.

However, although advantageous, this prior arrangement employed sensors that did not have access to the actual input and output supplied to the PA and instead was an open-loop system. As a result, the prior arrangement was only able to achieve an approximation of the idealized PA. To provide a much better linearization of the PA, linearization, in accordance with this disclosure, is again done in part in the analog domain and, in some embodiments, for each PA an analog NN is employed to make all PA behave as if it was an ideal PA. In particular, the NN may “idealize” each PA, i.e., cause it to behave like an ideal PA with a known amplification curve through the use of a closed-loop system. To this end, in accordance with the principles of this disclosure, the NN is provided with an indication of the actual input signal supplied to the PA and an indication of the actual output signal supplied in response thereto by the PA. Advantageously, as a result, each PA may be operated as an essentially perfect PA. The training of the analog NN may take place in the cloud and the linearization techniques may be employed with both analog and digital beamforming.

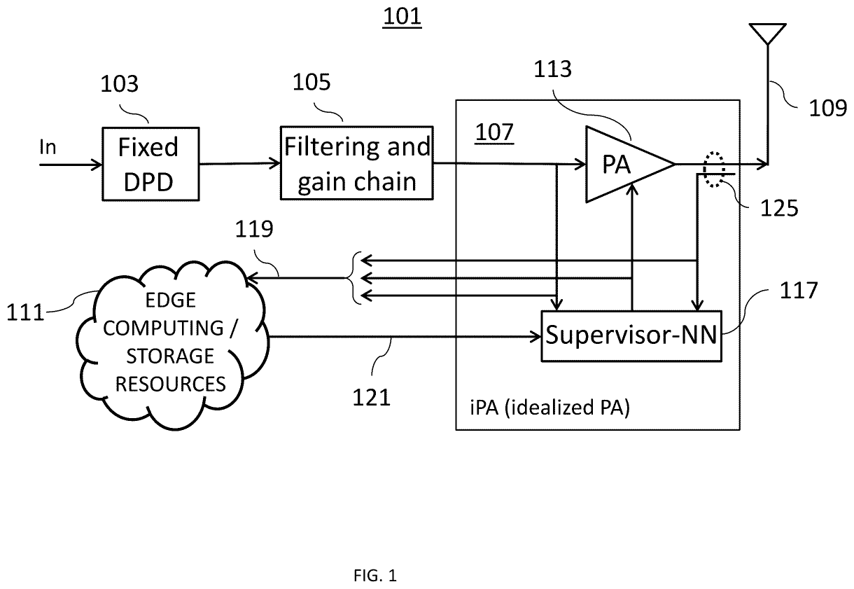

FIG. 1 shows an illustrative arrangement 101 of an embodiment of the disclosure that employs a fixed DPD and an idealized power amplifier (iPA), i.e., a power amplifier in that it has been arranged to behave as if it conforms to a known non-linear amplification curve through the use of a NN that responds to an indication of the actual input signal supplied to the PA and an indication of the actual output signal supplied in response thereto by the PA. More specifically, shown in FIG. 1 are fixed DPD 103, filtering and gain chain 105, iPA 107, antenna 109, and edge computing/storage resources 111.

Fixed DPD 103 is a feed-forward, non-adaptive linearizing element, e.g., a DPD, which adjusts the signal it receives as input to effectively linearize iPA 107 by performing DPD on the input signal. The signal supplied as input to fixed DPD 103 may be a baseband signal or a radio frequency (RF) signal. If the signal is at baseband then an upconverter to RF is required in filtering and gain stage 105 to upconvert the baseband signal before an RF signal can be supplied to iPA 107.

Filtering and gain chain 105, which is optional, implements certain filtering that may be desired, e.g., anti-aliasing filtering. Filtering and gain chain 105 may also include a gain stage that provides a certain level of amplification before the final amplification provided by iPA 107.

iPA 107 includes PA 113 and supervisor-neural network (NN) 117. iPA 107 behaves like an ideal PA with a known amplification curve regardless of various conditions such as temperature, voltage, technology process, of the PA and the like based on control signals provided by supervisor-NN 117.

PA 113 is a power amplifier whose behavior, i.e., amplification curve, is response to a control signal provided by supervisor-NN 117.

Supervisor-NN 117 is a neural network that supplies the control signal for PA 113. Supervisor-NN 117 is preferably analog, which, advantageously, is likely to achieve a higher degree of integration of parts of the system, e.g., onto a single die, and therefore lower cost, but it may be digital, e.g., implemented in a field programmable gate array (FPGA), in the alternative, or some combination thereof. In accordance with an aspect of the disclosure, supervisor-NN 117 receives as input an indication of the actual input signal supplied to PA 113 and an indication of the actual output signal supplied in response thereto by PA 113 and uses such indications to determine the output signal supplied to control PA 113. The indication of the actual input signal supplied to PA 113 may be via a direct tap from the input to PA 113 or it may be via a coupler that minimizes the effect on PA 113 of supplying some of its input signal for use by supervisor-NN 117. The indication of the actual output signal supplied by PA 113 is typically supplied via a coupler because the output signal of PA 113 is a high-power signal which would be too large for supervisor-NN 117 to handle and also so that what is sensed from PA 113 is not affected by having a portion thereof being supplied to supervisor-NN 117. Such a coupler may be a capacitive coupler that simply is an additional circuit board trace that is adjacent to the output trace of PA 113, which is shown in FIG. 1 as coupler 125. The supervisor-NN 117 may also be referred to herein as a supervisor or simply as NN.

Supervisor-NN 117 may be implemented as a well-known multilayer perceptron NN such as the one disclosed in G. Volanis, D. Maliuk, Y. Lu, K. S. Subramani, A. Antonopoulos and Y. Makris, “On-die learning-based self-calibration of analog/RF ICs,” 2016 IEEE 34th VLSI Test Symposium (VTS), Las Vegas, NV, USA, 2016, pp. 1-6, doi: 10.1109/VTS.2016.7477297 which is incorporated by reference as if fully set forth herein. Also see D. Maliuk and Y. Makris, “An Experimentation Platform for On-Chip Integration of Analog Neural Networks: A Pathway to Trusted and Robust Analog/RF ICs,” in IEEE Transactions on Neural Networks and Learning Systems, vol. 26, no. 8, pp. 1721-1734, August 2015, doi: 10.1109/TNNLS.2014.2354406; Y. Lu, K. S. Subramani, H. Huang, N. Kupp, K. Huang and Y. Makris, “A comparative study of one-shot statistical calibration methods for analog/RF ICs,” 2015 IEEE International Test Conference (ITC), Anaheim, CA, USA, 2015, pp. 1-10, doi: 10.1109/TEST.2015.7342415; and S. Haykin, Neural Networks: A Comprehensive Foundation. Prentice-Hall, 1998 each of which is also incorporated by reference as if fully set forth herein.

Supervisor-NN 117 may be trained in the cloud. To this end, the indication of the input supplied to PA 113, the indication of the actual output signal supplied in response thereto by PA 113, and the control signal output of supervisor-NN 117 may be supplied to edge computing/storage resources 111 by an uplink 119. A downlink 121 couples edge computing/storage resources 111 to supervisor-NN 117. Thus, uplink 119 is used to upload observation data, i.e., various data that is known at supervisor-NN 117, including a copy of the signal used to control PA 113, to edge computing/storage resources 111. Downlink 121 is employed to download control parameters, such as the weights produced as a result of the training process, to supervisor-NN 117. Each of links 119 and 121 may be any form of communication link, e.g., they may be implemented as or part of, without limitation, a wireless, cellular or wired network, a local area network (LAN), a wide area network (WAN), a metro area network (MAN), the Internet, the worldwide web (WWW), similar networks, and any combination thereof. Links 119 and 121 need not be the same form of communication link.

Advantageously, improved, and indeed substantially perfect, linearization performance is achieved without requiring feedback from PA 113. Further advantageously, a fixed DPD is much less expensive to implement than an adaptive DPD.

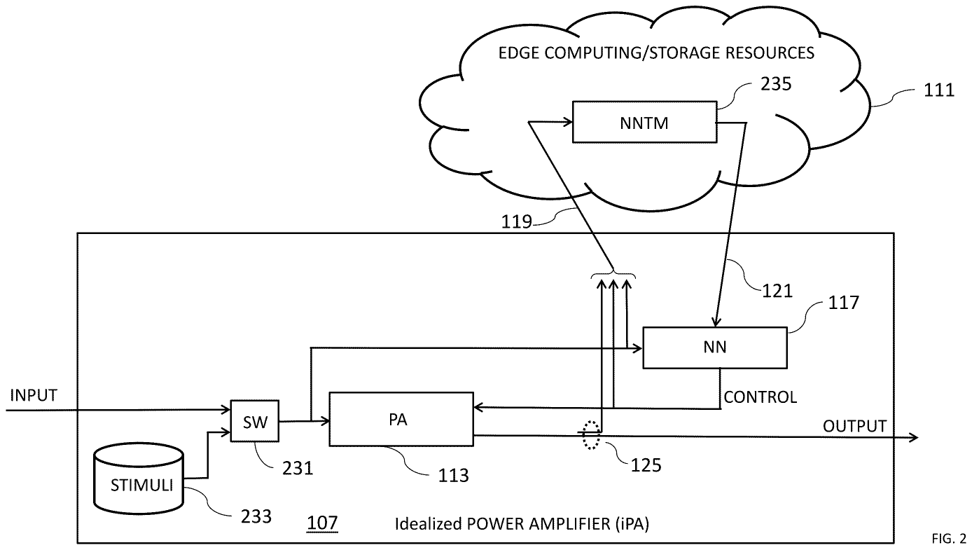

FIG. 2 shows a more detailed illustrative view of an embodiment of both iPA 107 and edge computing/storage resources 111 of FIG. 1. As shown in FIG. 2, iPA 107 includes PA 113, NN 117, optional coupler 125 as well as switch (SW) 231, and stimuli 233. The input to be amplified by iPA 107, e.g., output from filtering and gain chain 105, is supplied to SW 231. SW 231 also receives an input from stimuli 233 and, responsive to a control signal (not shown) supplies either the input received from filtering and gain chain 105 or the input received from stimuli 233 to PA 113 for amplification. iPA 107 may operate in a normal mode of operation, where SW 231 supplies the signal that is input to iPA 107 to PA 113. iPA 107 may also operate in an observation-only mode, where SW 231 supplies the output of stimuli 233 to PA 113. During this observation-only mode of operation, data stored in stimuli 233, such as pre-processed waveforms, are fed to the PA in order to test various aspects of its behavior.

NN 117 also receives control parameters, e.g., weights, from NN training mechanism (NNTM) 235, located in edge computing/storage resources 111, which are received via link 121. NN 117 provides as an output a control signal which is supplied as an input to PA 113 to control the behavior of PA 113. The control signal (CONTROL) produced as output by NN 117 is also supplied as an input to the NNTM 235 via link 119. The control signal may be based on the weights produced by NNTM 235 and received therefrom via link 121. The control signal produced by NN 117 may be used to adjust the operation of the PA. In one embodiment, the control signal is applied to tuning knobs of the PA which may correspond to bias voltages and currents used for adjusting the operation of the PA.

The input to PA 113, the output from PA 113, and the control signal are transmitted to NNTM 235. While this transmission may be performed on a continuous basis, such would result in a large volume of network traffic. Therefore, such transmission may be performed only occasionally, i.e., from time to time. To this end, the data may be stored in a local memory, e.g., a flash memory, not shown, prior to transmission. Similarly, in one embodiment, after the downloading of the initial set of control parameters, link 121 may be used occasionally to download updated versions of the parameters.

NNTM 235 may be located within edge computing/storage resources 111. It is used to train NN 117 based on the input to PA 113, the output from PA 113, and the control signal developed and supplied as output by NN 117 that is supplied thereto. More specifically, the input to PA 113, the output from PA 113, and the control signal developed and supplied as output by NN 117 are fed to NNTM 235.

In one embodiment, edge computing/storage resources 111 may maintain a copy of the contents of stimuli 233. Doing so enables edge computing/storage resources 111 to update the contents of stimuli 233 from time to time, e.g., via link 121 and further routing of such information within iPA 107. Typically, edge computing/storage resources 111 possesses much greater resources as compared to the resources available in iPA 107 and, furthermore, edge computing/storage resources 111 is generally expected to be the master of the overall training in that it supplies the weights employed in NN 117 which converts NN 117 into a trained neural network. NN 117 may be located on the same die as PA 113, while, as shown in the embodiment of FIG. 2, NNTM 235 may be located elsewhere, e.g., in the Cloud/Edge.

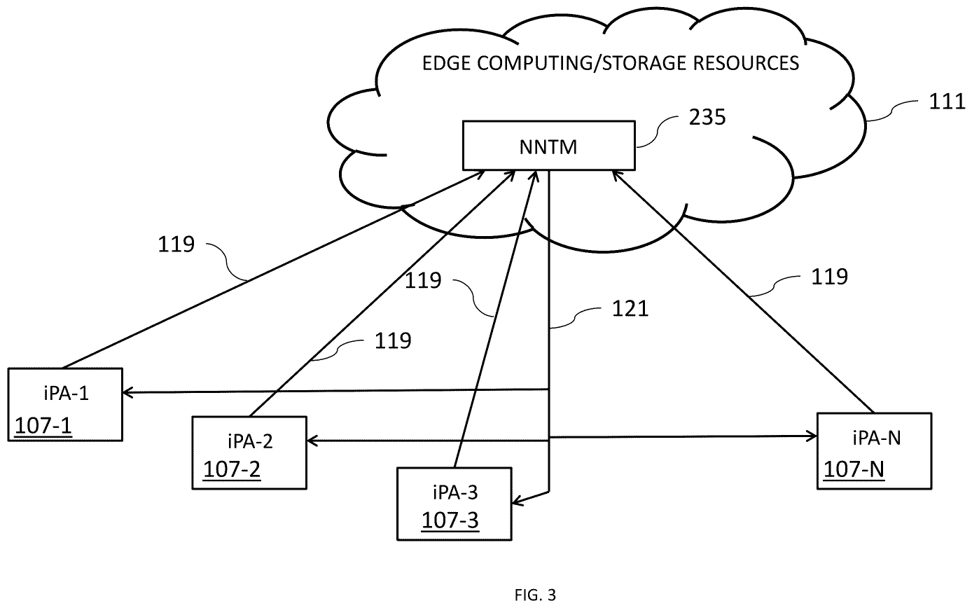

Multiple instantiations of iPA 107 that normally operate independently of each other may periodically send the same type of data from their own respective NN 117 to NNTM 235 for use in improving the weights supplied to at least one of the NN 117 of the iPAs 107. Such is shown in FIG. 3, where multiple iPAs 107, i.e., iPA 107-1 through 107-N, each structured as iPA 107 of FIG. 2, may each transmit their own input to PA 113, the output from PA 113, and the control signal developed and supplied as output by their NN 117, to NNTM 235 over a respective link 119 and receive from NNTM updated weights over link 121.

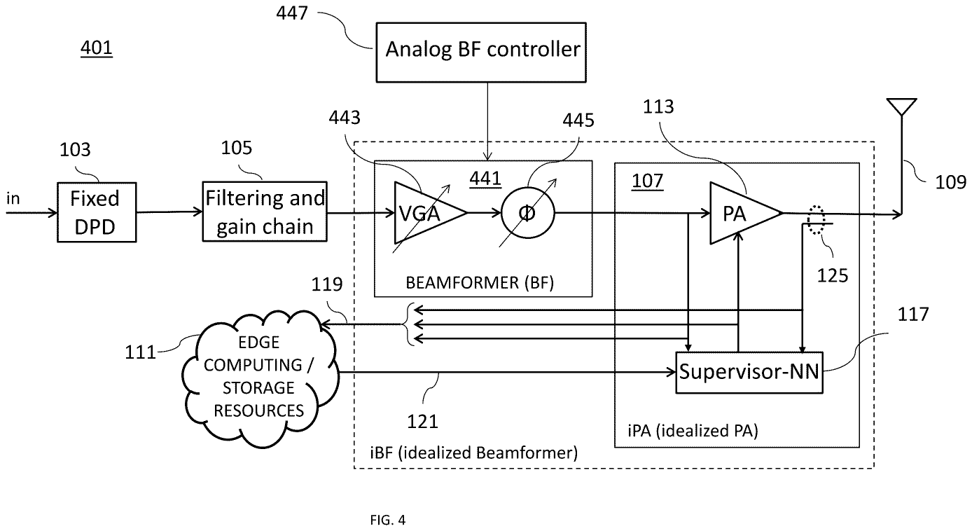

FIG. 4 shows an illustrative arrangement 401 of an embodiment of the disclosure that employs a fixed DPD and an idealized power amplifier (iPA) similar to that shown in FIG. 1 but which is attached to a single antenna for use with an analog beamforming implementation. To this end, idealized beamformer (iBF) has analog beamformer 441 interposed between filtering and gain chain 105 and iPA 107. Analog beamformer 441 includes variable gain amplifier (VGA) 443 and adjustable phase controller 445. In the embodiment shown, the signal supplied from filtering and gain chain 105 may first have its gain adjusted by VGA 443 and the adjusted amplified signal is supplied to adjustable phase controller 445 which may adjust its phase. In other embodiments, the ordering VGA 443 and adjustable phase controller 445 may be reversed. Regardless of the ordering, the resulting signal is then supplied as input to iPA 107, and in particular, to PA 113 therein.

Analog beamformer (BF) controller 447 supplies the control signals to beamformer 441 which are used to adjust the gain of VGA 443 and the phase adjustment provided by adjustable phase controller 445. In one embodiment, VGA 443 and adjustable phase controller 445 are analog components. Advantageously, analog beamforming enables providing semi-static beamforming, for example, enabling radio features such as tilt control or dynamic sectorization. Analog BF controller 447 receives control signals from higher protocol layers, e.g., processors of the higher layer protocol (not shown) that specify what beamforming should be performed. In one embodiment, analog BF controller 447 is implemented as a digital signal processor (DSP).

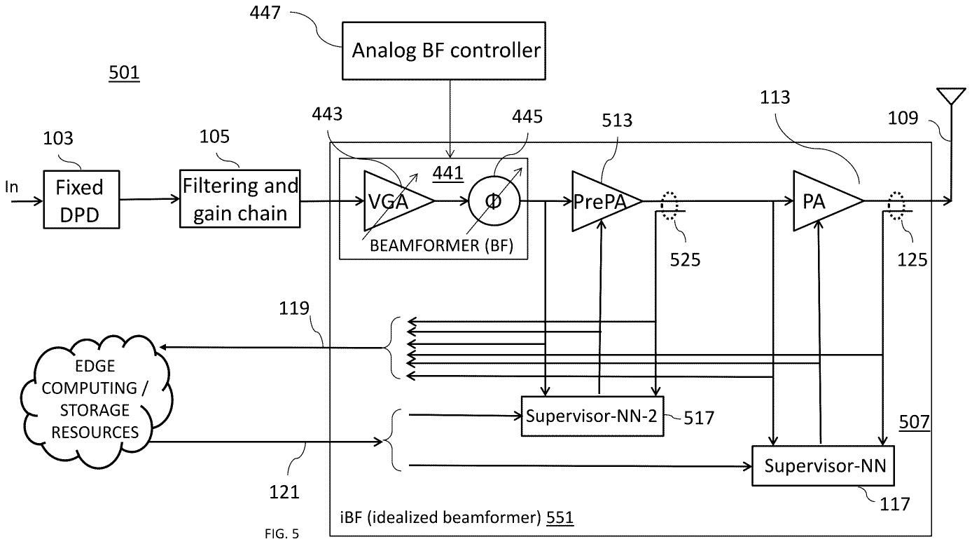

FIG. 5 shows an illustrative arrangement 501 of an embodiment of the disclosure that employs a single fixed DPD and an idealized power amplifier (iPA) while implementing analog beamforming similar to that shown in FIG. 4 but which further employs a pre-power amplifier that is further controlled by an additional neural network. New in FIG. 5, within iBF 551, are pre-power amplifier (PrePA) 513, coupler 525, and supervisor-NN-2 517. In other words, a single fixed DPD is used to control consecutive amplifiers. PrePA 513 is an amplifier which may be similar or different from PA 113. Supervisor-NN-2 is a neural network that operates similarly to supervisor-NN 117 but may have different weights that are provided from edge computing/storage resources 111, e.g., from an NNTM therein. Although in the embodiment shown in FIG. 5 the signals relevant to supervisor-NN 117 as well as and the signals relevant to supervisor-NN-2 517 share links 119 and 121 to communicate with edge computing/storage resources 111 in other embodiments supervisor-NN 117 and supervisor-NN-2 517 may have their own independent links to edge computing/storage resources 111 in any combination. Indeed, they could even share one of the links and each have their own independent links for the other.

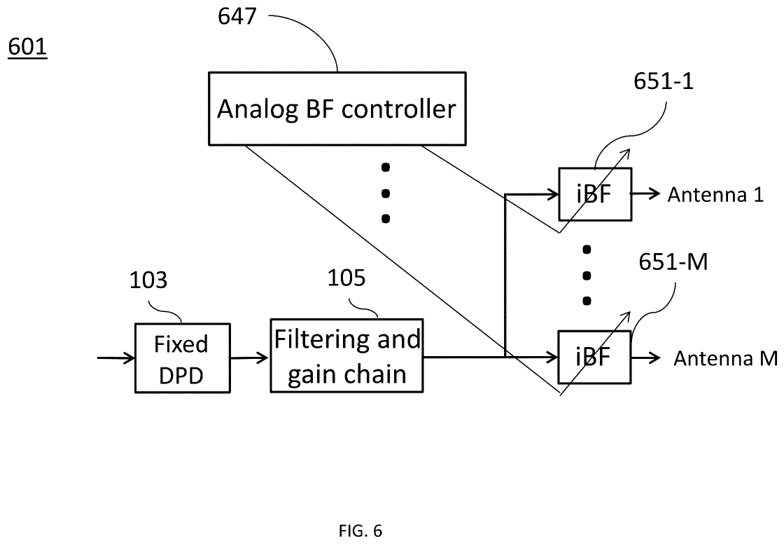

FIG. 6 shows an illustrative arrangement 601 of an embodiment of the disclosure that employs a single fixed DPD and at least two idealized beamformers arranged in accordance with the principles of the disclosure to implement analog beamforming. In the embodiment shown, fixed DPD 103 and filtering and gain chain 105 supply a signal, e.g., in manner similar to that shown in FIGS. 1, 4, and 5, to each of iBF 651-1 to 651-M, where M is an integer greater than or equal to two. Each of iBF 651 may have an internal structure such as that of iBF 451 or iBF 551 described hereinabove. The beamforming control signals are supplied to each respective iBF 651 by analog beamformer (BF) controller 647.

More specifically analog beamformer (BF) controller 647 supplies the control signals which are used to adjust the gain of each VGA and the phase of each adjustable phase controller within the various iBFs 651. Analog BF controller 647 receives control signals from higher protocol layers, e.g., processors of the higher layer protocol (not shown) that specify what beamforming should be performed. In one embodiment, analog BF controller 647 is implemented as a digital signal processor (DSP).

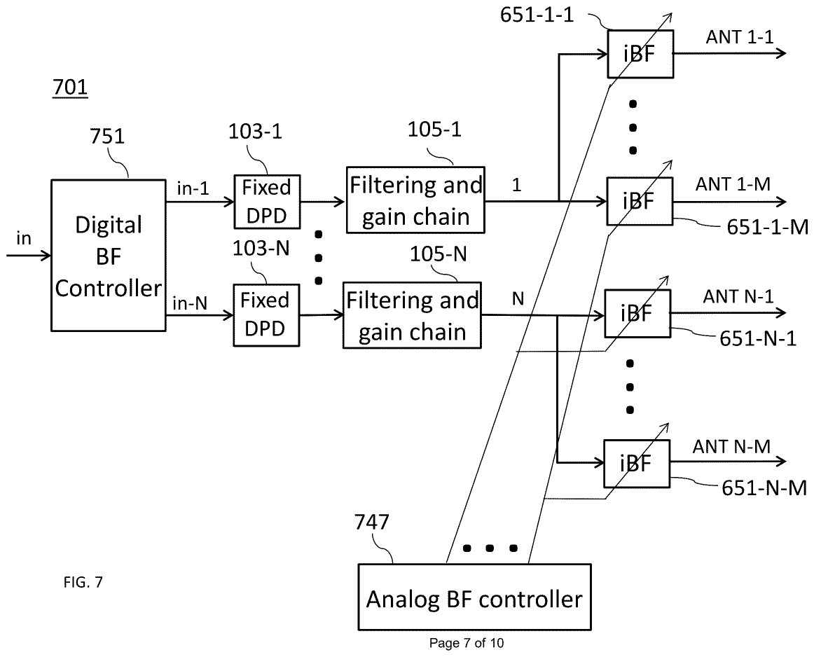

FIG. 7 shows an illustrative arrangement 701 of a hybrid analog-digital beamforming radio in accordance with an embodiment of the disclosure. Digital beamforming (BF) controller 751 receives a digital signal in as input and supplies as output N signals, in-1 to in-N, where N is an integer greater than one, where each output signal is supplied to a signal pathway such as that shown in FIG. 6. More specifically, each signal pathway has a fixed DPD and a filtering and gain chain, where each fixed DPD is designated 103 with an appropriate suffix corresponding to the pathway to which it belongs, e.g., DPD 103-1 and DPD 103-N and each filtering and gain chain is designated 105 with an appropriate suffix corresponding to the pathway to which it belongs, e.g., filtering and gain chain 105-1 and filtering and gain chain 105-N.

The output of each filtering and gain chain 105 is supplied to M idealized beamformers which further implement analog beamforming. Each of the idealized beamformers is designated 651 with appropriate suffixes corresponding to the pathway to which it belongs and which of the M iBFs of the chain that it is, e.g., iBF 651-1-1 to iBF 651-1-M for the pathway corresponding to in-1 and iBF 651-N-1 to iBF 651-N-M for the pathway corresponding to in-N. The output of each of iBF 651 of FIG. 7 are supplied to respective antennas, not shown. The control signals for the analog beamforming are supplied to each respective iBF 651 by analog beamformer (BF) controller 747.

Analog beamformer (BF) controller 747 supplies the control signals which are used to adjust the gain of each VGA and the phase of each adjustable phase controller within the various iBFs 651. Analog BF controller 747 receives control signals from higher protocol layers, e.g., processors of the higher layer protocol (not shown) that specify what beamforming should be performed. In one embodiment, analog BF controller 747 is implemented as a digital signal processor (DSP).

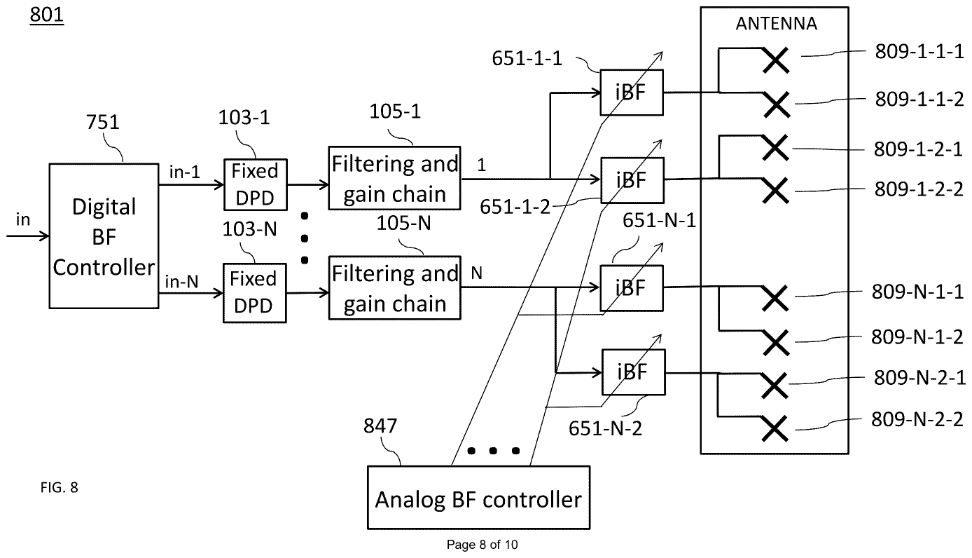

FIG. 8 shows an illustrative arrangement 801 of a hybrid analog-digital beamforming radio in accordance with another embodiment of the disclosure. Similar to the embodiment of FIG. 7, digital beamforming (BF) controller 751 receives a digital signal in as input and supplies as output N signals, in-1 to in-N, where N is an integer greater than one, where each output signal is supplied to a signal pathway such as that shown in FIG. 6. More specifically, each signal pathway has a fixed DPD and a filtering and gain chain, where each fixed DPD is designated 103 with an appropriate suffix corresponding to the pathway to which it belongs, e.g., DPD 103-1 and DPD 103-N and each filtering and gain chain is designated 105 with an appropriate suffix corresponding to the pathway to which it belongs, e.g., filtering and gain chain 105-1 and filtering and gain chain 105-N.

The output of each filtering and gain chain 105 is supplied to 2 idealized beamformers which further implement analog beamforming. Each of the idealized beamformers is designated 651 with appropriate suffixes corresponding to the pathway to which it belongs and which of the two iBFs it is, e.g., iBF 651-1-1 and iBF 651-1-2 for the pathway corresponding to in-1 and iBF 651-N-1 and iBF 651-N-2 for the pathway corresponding to in-N. The output of each of iBF 651 of FIG. 8 are supplied to two of antennas 809. Each of the antennas are designated as 809 with the same suffix as the iBF to which it is connected plus a further suffix of 1 or 2 indicating which of the two antennas coupled to the iBF it is. The control signals for the analog beamforming are supplied to each respective iBF 651 by analog beamformer (BF) controller 847.

Analog beamformer (BF) controller 847 supplies the control signals which are used to adjust the gain of each VGA and the phase of each adjustable phase controller within the various iBFs 651. Analog BF controller 847 receives control signals from higher protocol layers, e.g., processors of the higher layer protocol (not shown) that specify what beamforming should be performed. In one embodiment, analog BF controller 847 is implemented as a digital signal processor (DSP).

While the foregoing has been presented in terms of a PA in a wireless communication system, those of ordinary skill in the art will readily recognize that the foregoing techniques can be applied to any amplifier that needs to be linearized, i.e., idealized.

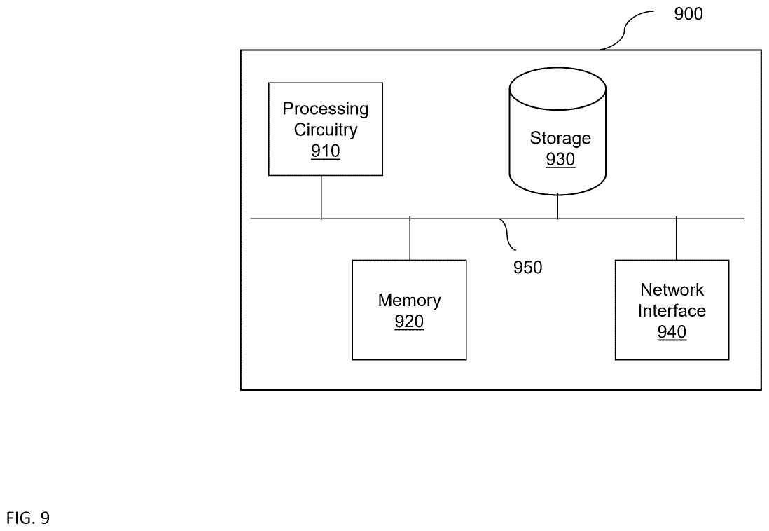

FIG. 9 shows an illustrative system 900 according to an embodiment. The system 900 may be used to implement the various analog beamforming controllers, the digital beamforming controller and the NNTM described hereinabove. The system 900 includes a processing circuitry 910 coupled to a memory 920, a storage 930, and a network interface 940. In an embodiment, the components of the system 900 may be communicatively connected via a bus 950.

The processing circuitry 910 may be realized as one or more hardware logic components and circuits. For example, and without limitation, illustrative types of hardware logic components that can be used include field programmable gate arrays (FPGAs), application-specific integrated circuits (ASICs), Application-specific standard products (ASSPs), system-on-a-chip systems (SOCs), graphics processing units (GPUs), tensor processing units (TPUs), general-purpose microprocessors, microcontrollers, digital signal processors (DSPs), and the like, or any other hardware logic components that can perform calculations or other manipulations of information.

The memory 920 may be volatile, e.g., random access memory, etc., non-volatile, e.g., read only memory, flash memory, etc., or a combination thereof.

In one configuration, software for implementing one or more embodiments disclosed herein may be stored in the storage 930. In another configuration, the memory 920 is configured to store such software. Software shall be construed broadly to mean any type of instructions, whether referred to as software, firmware, middleware, microcode, hardware description language, or otherwise. Instructions may include code, e.g., in source code format, binary code format, executable code format, or any other suitable format of code. The instructions, when executed by the processing circuitry 910, cause the processing circuitry 910 to perform the various processes described herein.

The storage 930 may be magnetic storage, optical storage, and the like, and may be realized, for example, as flash memory or other memory technology, compact disk-read only memory (CD-ROM), Digital Video Disks (DVDs), or any other medium which can be used to store the desired information.

The network interface 940 allows the system 900 to communicate with, for example, an idealized power amplifier or a beamformer of an idealized beamformer, or other, e.g., digital, portions of a wireless communication system.

It should be understood that the embodiments described herein are not limited to the specific architecture illustrated in FIG. 9, and other architectures may be equally used without departing from the scope of the disclosed embodiments.

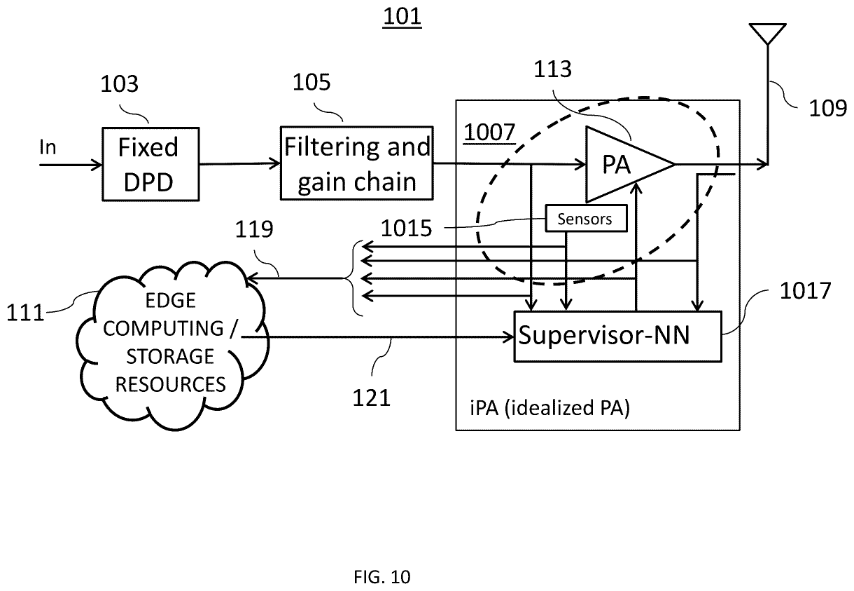

FIG. 10 shows an embodiment similar to that of FIG. 1 but where the iPA, now designated iPA 1007, further including sensors 1015 that may sense various conditions such as temperature, voltage, technology process, and the like, in or adjacent to PA 113. Such sensors may be integrated with or simply in the vicinity of, e.g., adjacent to PA 113. Indications of the conditions detected by sensors 1015 are supplied as input to supervisor-NN 1017 and also transmitted to edge computing/storage resources 111, e.g., over link 119. Supervisor-NN 1017 is similar to supervisor-NN 117 but it also receives as input the indications of the conditions sensed by sensors 1015 and uses such indications to determine the output signal supplied to control PA 113.

The input to PA 113, the output from PA 113, the sensor data from sensors 1015, and the control signal are transmitted to NNTM 235. While this transmission may be performed on a continuous basis, such would result in a large volume of network traffic. Therefore, such transmission may be performed only occasionally, i.e., from time to time. To this end, the sensor data may be stored in a local memory, e.g., a flash memory, not shown, prior to transmission. In one embodiment, only a small portion of the sensor data is transmitted to NNTM 235. As such, link 119 may only rarely or even very rarely carry the sensor data in order to supply information regarding very slow changes at iPA 1007, such as the aging of the circuit, which is sufficient to enable correction of such conditions using updated information received via link 121. Similarly, in one embodiment, after the downloading of the initial set of control parameters, link 121 may be used occasionally to download updated versions of the parameters.

Using sensors 1015 may assist in startup to more quickly achieve idealization by providing an initial direction to change the control signal which is then fine-tuned using the actual input and output signal of the PA.

iPAs such as iPA 1007 may be employed in any of the other embodiments disclosed herein where an iPA is called for, e.g., where iPA 107 is shown.

The various embodiments disclosed herein can be implemented as hardware, firmware, firmware executing on hardware, software, software executing on hardware, or any combination thereof. Moreover, the software is implemented tangibly embodied on a program storage unit or computer readable medium consisting of parts, or of certain devices and/or a combination of devices. The application program may be uploaded to, and executed by, a machine comprising any suitable architecture. Preferably, the machine is implemented on a computer platform having hardware such as one or more central processing units (CPUs), a memory, and input/output interfaces. The computer platform may also include an operating system and microinstruction code. The various processes and functions described herein may be implemented as either part of the microinstruction code or part of the application program, or any combination thereof, which may be executed by a CPU, whether or not such a computer or processor is explicitly shown. In addition, various other peripheral units may be connected to the computer platform such as an additional data storage unit and a printing unit. Furthermore, a non-transitory computer readable medium is any computer readable medium except for a transitory propagating signal.

All examples and conditional language recited herein are intended for pedagogical purposes to aid the reader in understanding the principles of the disclosed embodiment and the concepts contributed by the inventor to furthering the art and are to be construed as being without limitation to such specifically recited examples and conditions. Moreover, all statements herein reciting principles, aspects, and embodiments of the disclosed embodiments, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

It should be understood that any reference to an element herein using a designation such as “first,” “second,” and so forth does not generally limit the quantity or order of those elements. Rather, these designations are generally used herein as a convenient method of distinguishing between two or more elements or instances of an element. Thus, a reference to first and second elements does not mean that only two elements may be employed there or that the first element must precede the second element in some manner. Also, unless stated otherwise, a set of elements comprises one or more elements.

As used herein, the phrase “at least one of” followed by a listing of items means that any of the listed items can be utilized individually, or any combination of two or more of the listed items can be utilized. For example, if a system is described as including “at least one of A, B, and C,” the system can include A alone; B alone; C alone; 2A; 2B; 2C; 3A; A and B in combination; B and C in combination; A and C in combination; A, B, and C in combination; 2A and C in combination; A, 3B, and 2C in combination; and the like.

The following merely illustrates the principles of the invention. It will thus be appreciated that those skilled in the art will be able to devise various arrangements that, although not explicitly described or shown herein, embody the principles of the invention and are included within its spirit and scope. Furthermore, all examples and conditional language recited herein are principally intended expressly to be only for pedagogical purposes to aid the reader in understanding the principles of the invention and the concepts contributed by the inventor(s) to furthering the art and are to be construed as being without limitation to such specifically recited examples and conditions. Moreover, all statements herein reciting principles, aspects, and embodiments of the invention, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

Note that wherever a signal that is transmitted from a transmit antenna is referred to, in systems without antennas such phraseology may be considered to refer to signal supplied to a transmit branch. Similarly, the number of transmit branches may be substituted for the number of transmit antennas.

Likewise, wherever a signal that originates at a receive antenna is referred to, in systems without antennas such phraseology may be considered to refer to a signal arriving at a receive branch. Similarly, the number of receive branches may be substituted for the number of receive antennas.

Herein, the term 5G is meant to refer to the next generation of mobile networks as specified by the International Telecommunications Union-Radio communications sector (ITU-R), referred to as 4G standards which is well known to those of ordinary skill in the related art.

Unless otherwise explicitly specified herein, the drawings are not drawn to scale.

In the description, identically numbered components within different ones of the FIGs. refer to components that are substantially the same.

What is claimed is:

1. Apparatus for causing a power amplifier (PA) to act as an idealized power amplifier (iPA), comprising:
a fixed digital predistortion (DPD) circuit;
a PA coupled to the DPD circuit, the PA receiving as an input a version of a signal supplied as an output by the DPD and the PA supplying as an output an amplified version of the PA input; and
a neural network adapted to control a level of amplification provided by the PA;
wherein the neural network receives an indication of the input to the PA and an indication of output of the PA and controls the level of amplification provided by the PA based on the received indications.

2. The apparatus of claim 1, wherein neural network controls level of amplification provided by the PA at least based on contemporaneously received ones of the indication of the input to the PA and the indication of the output of the PA.

3. The apparatus of claim 1, wherein neural network receives the indication input via a tap from the input to the PA.

4. The apparatus of claim 1, further comprising a coupler, wherein neural network receives the indication input of the PA via the coupler.

5. The apparatus of claim 1, further comprising a coupler, wherein neural network receives the indication output of the PA via the coupler.

6. The apparatus of claim 5, wherein the coupler is a capacitive coupler.

7. The apparatus of claim 1, wherein the neural network receives control parameters from a remote source.

8. The apparatus of claim 7, wherein the control parameters are weights to be employed by the neural network.

9. The apparatus of claim 7, wherein the control parameters are received from the remote source over a communications link.

10. The apparatus of claim 7, wherein at least from time to time the indication of the input to the PA and the indication of output of the PA are supplied to the remote source.

11. The apparatus of claim 1, further comprising an analog beamformer interposed between the fixed DPD and the PA, the analog beamformer receiving an input signal and controlling at least one of a phase and an amplitude of an output signal that is based on the input signal, the output signal being supplied to the PA.

12. The apparatus of claim 11, further comprising an analog beamformer controlling circuit coupled to the analog beamformer and supplying control signals to adjust at least one of the phase and amplitude controlled by the analog beamformer.

13. The apparatus of claim 11, further comprising a digital beamformer controlling circuit supplying an input signal to the fixed DPD circuit.

14. The apparatus of claim 1 further comprising:
a prepower amplifier (PrePA) coupled to the DPD circuit, PrePA being interposed between the DPD circuit and the PrePA, the PrePA receiving as an input a version of a signal supplied as an output by the DPD and supply an amplified version thereof as an output to the PA;
a second neural network; and
wherein the second neural network receives an indication of the input to the PrePA and an indication of output of the PrePA and controls the level of amplification provided by the PrePA based on the received indications.

15. The apparatus of claim 1, wherein an output of the PA is coupled to at least one antenna.

16. The apparatus of claim 1, wherein the fixed DPD is coupled to a plurality of PAs.

17. The apparatus of claim 1, further comprising:
at least one sensor adapted to determine at least one condition related to of the power amplifier;
wherein the neural network is further adapted to control the level of amplification provided by the power amplifier based on a measurement of the at least one condition as measured by the at least one sensor.

18. The apparatus of claim 17, wherein an indication of the at least one condition determined by the at least one sensor is supplied to a remote source of control parameters for the neural network and wherein the neural network receives control parameters from the remote source over a communications link, the control parameters being based at least on the indication of the at least one condition.

19. The apparatus of claim 1, further comprising a filtering and gain chain interposed between the fixed DPD and the PA.

20. A beamforming transmitter for use in wireless communication, comprising
a plurality of fixed digital predistortion (DPD) circuits each receiving a respective input for transmission and supplying as an output an adjusted version of its received input;
a plurality of filtering and gain chains, each of the plurality of filtering and gain chains receiving as input a respective one of the adjusted versions of the inputs; and
a plurality of idealized beamformers (iBFs), each iBF of the plurality being coupled to receive as input an output supplied from one of the filtering and chain gains and supplying as output an amplified version of its respective received input for transmission by at least one antenna, wherein each of the filtering and gain chains supplies its output to a plurality of the iBFs, wherein each iBF comprises:
a power amplifier (PA);
a neural network adapted to control a level of amplification provided by the PA based an indication of the input to the PA and an indication of output of the PA which are supplied to the neural network; and
an analog beamformer interposed between input to the iBF and the PA of the iBF, the analog beamformer controlling at least one of phase and amplitude of an output signal based on the input to the iBF.

21. The beamforming transmitter of claim 20, wherein the neural network receives control parameters from a remote source.

22. The beamforming transmitter of claim 21, wherein the control parameters are weights to be employed by the neural network.

23. The beamforming transmitter of claim 21, wherein the control parameters are received from the remote source over a communications link.

24. The beamforming transmitter of claim 21, wherein at least from time to time the indication of the input to the PA and the indication of output of the PA are supplied to the remote source.

25. The beamforming transmitter of claim 20, further comprising an analog beamformer controlling circuit coupled to each respective one of the analog beamformers and supplying respective control signals to adjust at least one of a phase and amplitude controlled by each of the respective analog beamformers.

26. The beamforming transmitter of claim 20, further comprising a digital beamformer controlling circuit supplying each of the inputs for transmission that are supplied to each respective one of the fixed DPD circuits.

27. The beamforming transmitter of claim 20, wherein each of the iBFs is adapted to couple its output to a plurality of antennas.

28. The beamforming transmitter of claim 20, further comprising a plurality of antennas, wherein each of the iBFs couples its output to at least one of the antennas.
